(19) United States
(12) Patent Application Publication
(10) Pub. No.: US 2025/0015226 A1
(43) Pub. Date: Jan. 9, 2025

(54) METHOD OF MANUFACTURING LIGHT-EMITTING ELEMENT

(71) Applicant: NICHIA CORPORATION, Anan-shi (JP)

(72) Inventor: Naoto FURUHA, Kaifu-gun (JP)

(73) Assignee: NICHIA CORPORATION, Anan-shi (JP)

(21) Appl. No.: 18/760,808

(22) Filed: Jul. 1, 2024

(30) Foreign Application Priority Data
Jul. 6, 2023 (JP) 2023-111163

(51) Int. Cl. H01L 33/00

(52) U.S. Cl. CPC H01L 33/0095

(57) ABSTRACT

A method of manufacturing a light-emitting element includes: preparing a wafer including a substrate, and a semiconductor structure disposed on the substrate; and forming a plurality of light-emitting element regions by dividing the semiconductor structure. The forming of the plurality of light-emitting element regions includes: forming a plurality of first masks on the semiconductor structure such that each of the plurality of first masks covers a respective first region where one of the plurality of light-emitting element regions is to be formed, and each of the plurality of first masks has an area greater than an area of the respective first region in a plan view, and exposing the substrate through the semiconductor structure by removing a portion of the semiconductor structure that is not covered by the plurality of first masks.

### CROSS-REFERENCE TO RELATED APPLICATIONS

This application is based on and claims priority to Japanese Patent Application No. 2023-111163, filed on Jul. 6, 2023, the entire contents of which are incorporated herein by reference.

### TECHNICAL FIELD

The present disclosure relates to a method of manufacturing a light-emitting element.

### BACKGROUND

Japanese Patent Publication No. 2017-195370 proposes a light-emitting element in which a plurality of light emitting cells are disposed on a substrate. In a process of manufacturing such a light-emitting element, a plurality of light emitting cells are formed by dividing a semiconductor structure disposed on a substrate. When the semiconductor structure is divided, etching is performed by using resist masks that cover portions of the semiconductor structure, where light emitting cells are to be formed, and expose the other portions.

In a case where a relatively thick semiconductor structure is etched as in a conventional method of manufacturing a light-emitting element, a mismatch between the shape of a designed light-emitting element region and the shape of an obtained light-emitting element region is likely to be large.

### SUMMARY

It is an object of the present disclosure to provide a method of manufacturing a light-emitting element that can reduce a mismatch between the shape of a designed light-emitting element region and the shape of an obtained light-emitting element region.

According to an aspect of the present disclosure, a method of manufacturing a light-emitting element includes preparing a wafer including a substrate and a semiconductor structure disposed on the substrate; and forming a plurality of light-emitting element regions by dividing the semiconductor structure. The forming of the plurality of light-emitting element regions includes forming a plurality of first masks on the semiconductor structure, and exposing the substrate through the semiconductor structure by removing a portion of the semiconductor structure that is not covered by each of the plurality of first masks. In the forming of the plurality of first masks, each of the plurality of first masks covers a first region where one of the plurality of light-emitting element regions is to be formed, and each of the plurality of first masks has an area greater than an area of the first region in a plan view.

### BRIEF DESCRIPTION OF THE DRAWINGS

Other objects and further features of the present invention will be apparent from the following detailed description when read in conjunction with the accompanying drawings, in which:

FIG. 1 is a top view (part 1) illustrating a method of manufacturing a light-emitting element according to an embodiment;

FIG. 2 is a top view (part 2) illustrating the method of manufacturing the light-emitting element according to the embodiment;

FIG. 3 is a top view (part 3) illustrating the method of manufacturing the light-emitting element according to the embodiment;

FIG. 4 is a top view (part 4) illustrating the method of manufacturing the light-emitting element according to the embodiment;

FIG. 5 is a top view (part 5) illustrating the method of manufacturing the light-emitting element according to the embodiment;

FIG. 6 is a top view (part 6) illustrating the method of manufacturing the light-emitting element according to the embodiment;

FIG. 7 is a top view (part 7) illustrating the method of manufacturing the light-emitting element according to the embodiment;

FIG. 8 is a top view (part 8) illustrating the method of manufacturing the light-emitting element according to the embodiment;

FIG. 9 is a top view illustrating a first region where a light-emitting element region is to be formed;

FIG. 10 is a top view illustrating a first mask;

FIG. 11 is a cross-sectional view (part 1) illustrating the method of manufacturing the light-emitting element according to the embodiment;

FIG. 12 is a cross-sectional view (part 2) illustrating the method of manufacturing the light-emitting element according to the embodiment;

FIG. 13 is a cross-sectional view (part 3) illustrating the method of manufacturing the light-emitting element according to the embodiment;

FIG. 14 is a cross-sectional view (part 4) illustrating the method of manufacturing the light-emitting element according to the embodiment;

FIG. 15 is a cross-sectional view (part 5) illustrating the method of manufacturing the light-emitting element according to the embodiment;

FIG. 16 is a cross-sectional view (part 6) illustrating the method of manufacturing the light-emitting element according to the embodiment;

FIG. 17 is a cross-sectional view (part 7) illustrating the method of manufacturing the light-emitting element according to the embodiment; and

FIG. 18 is a cross-sectional view (part 8) illustrating the method of manufacturing the light-emitting element according to the embodiment.

### DETAILED DESCRIPTION

Embodiments of the present disclosure will be described below with reference to the accompanying drawings. The following description is provided for the purpose of embodying the technical ideas of the present disclosure, but the present disclosure is not limited to the embodiments in the following description unless specifically stated.

In the drawings, members having the same functions may be denoted by the same reference numerals. In consideration of ease of explanation or ease of understanding of key points, configurations may be illustrated in separate embodiments for the sake of convenience; however, such configurations illustrated in different embodiments or examples can be partially substituted or combined with one another. A description of an embodiment given after a description of another embodiment will be focused mainly on matters different from those of the previously described embodiment, and a duplicate description of matters common to the already described embodiment may be omitted. The sizes, positional relationships, and the like of members illustrated in the drawings may be exaggerated for clearer illustration. In order to avoid excessive complication of the drawings, a schematic view in which some elements are not illustrated may be used, or an end view illustrating only a cut surface may be used as a cross-sectional view. Further, an XYZ orthogonal coordinate system is used in the following description; however, the coordinate system is defined for the purpose of description and does not limit the orientation of a substrate or the like. In addition, when viewed from a given point, a +Z side may be referred to as upper, an upper side, or above, and a −Z side may be referred to as lower, a lower side, or below.

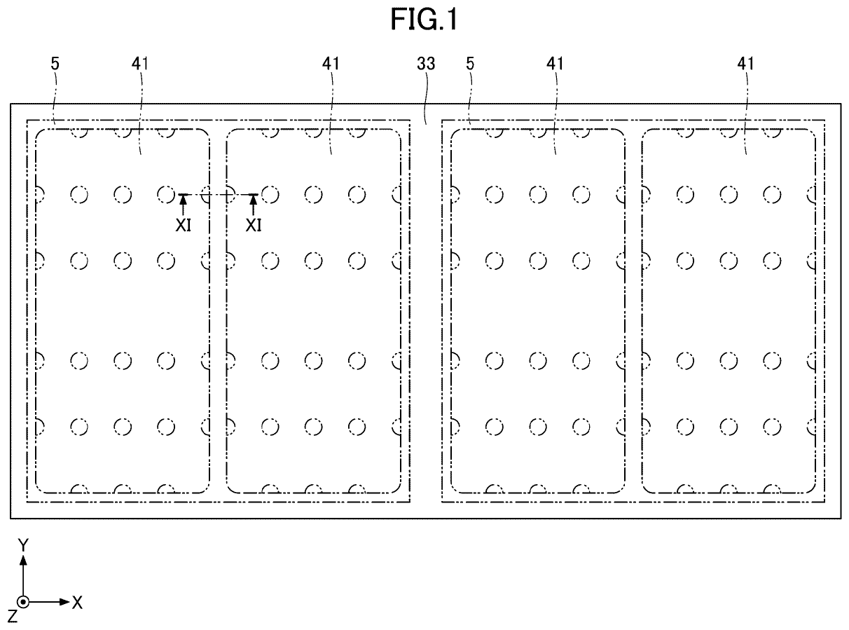

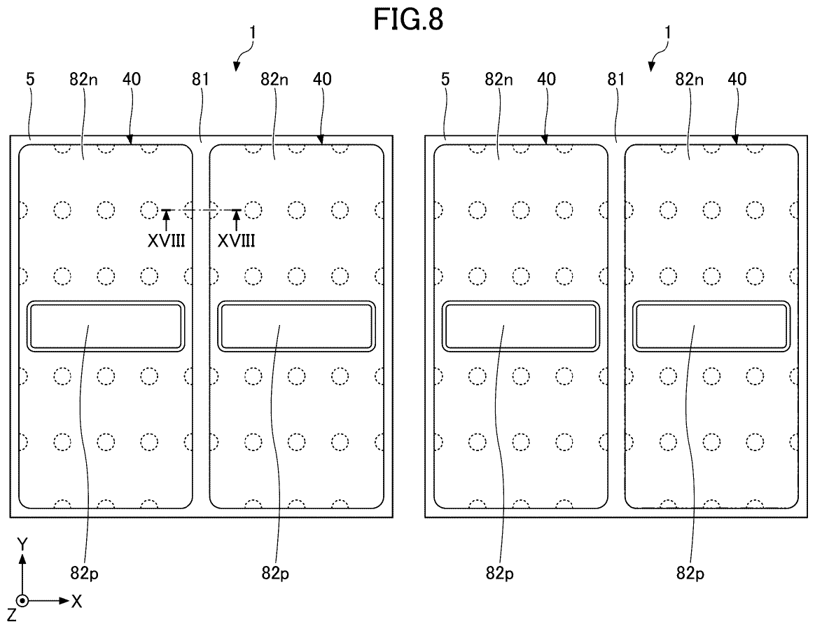

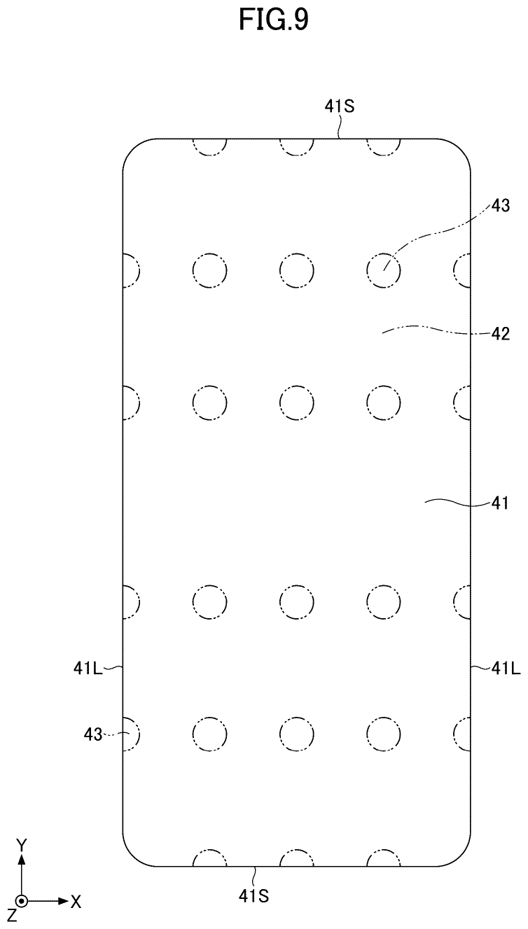

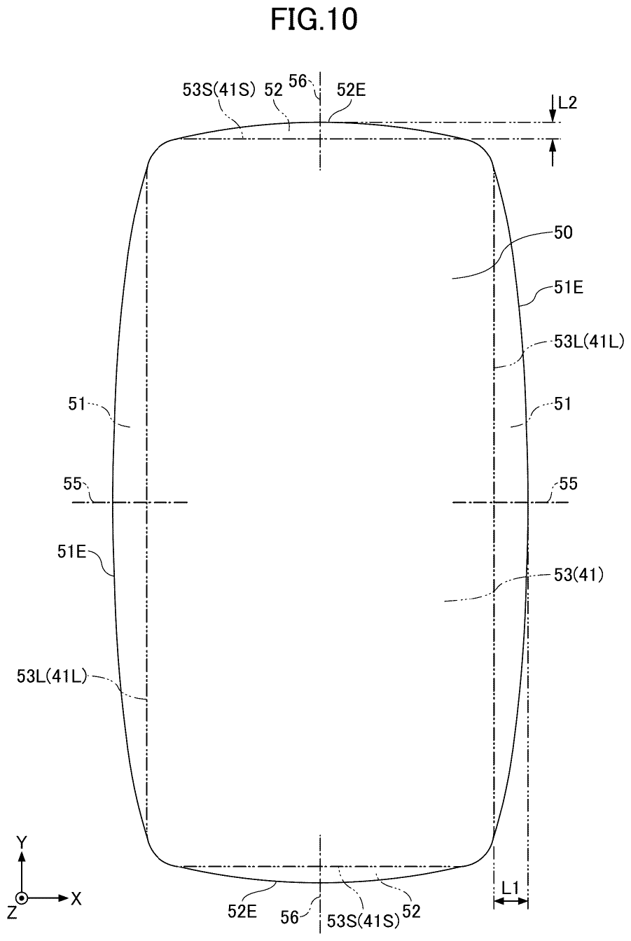

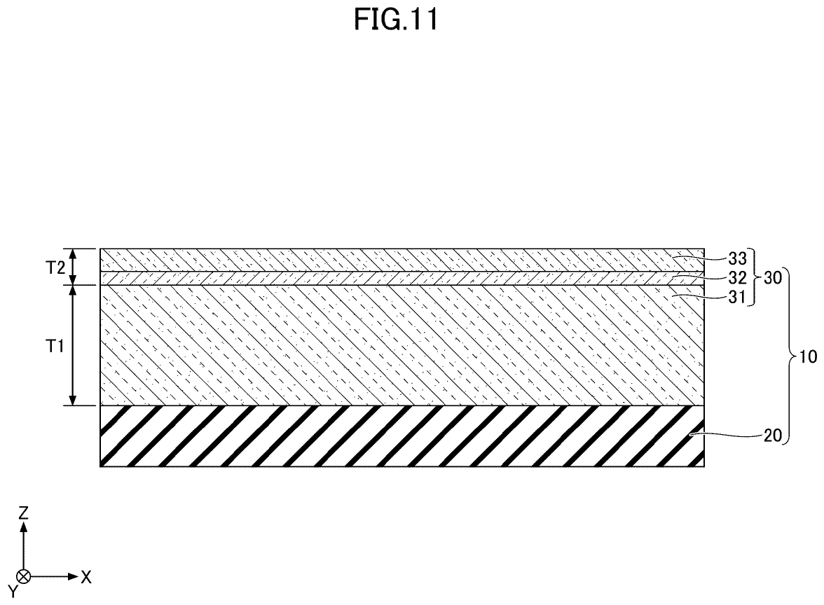

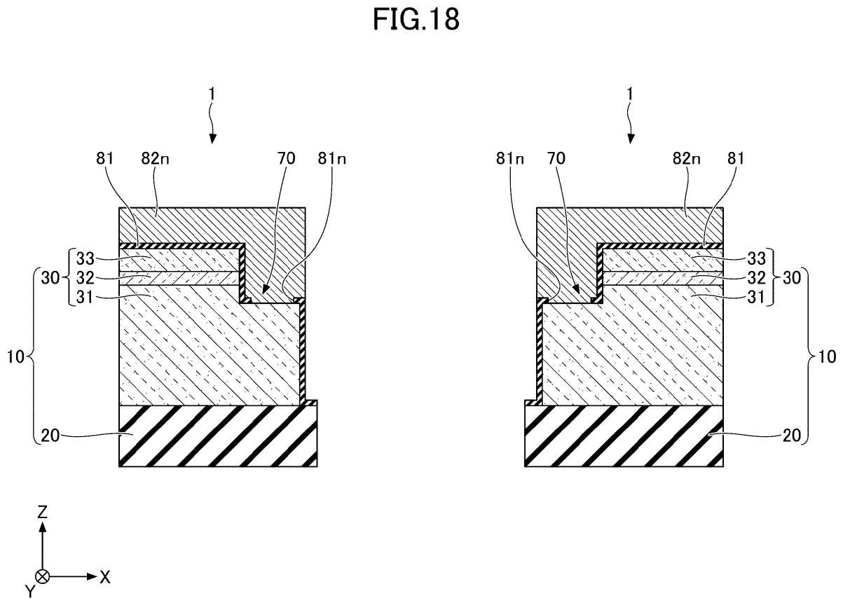

An embodiment relates to a method of manufacturing a light-emitting element. FIGS. 1 to 8 are top views illustrating the method of manufacturing the light-emitting element according to the embodiment. FIG. 9 is a top view illustrating a first region where a light-emitting element region is to be formed. FIG. 10 is a top view illustrating a first mask. FIGS. 11 to 18 are cross-sectional views illustrating the method of manufacturing the light-emitting element according to the embodiment. FIGS. 11 to 18 correspond to cross-sectional views taken through lines XI-XI, XII-XII, XIII-XIII, XIV-XIV, XV-XV, XVI-XVI, XVII-XVII, and XVIII-XVIII of FIGS. 1 to 8, respectively. In the present embodiment, a light-emitting element 1 illustrated in FIG. 8 and FIG. 18 is manufactured. The light-emitting element 1 has two light-emitting element regions 40 arranged in the X direction.

In the present embodiment, as illustrated in FIG. 1 and FIG. 11, first, a step of preparing a wafer 10 including a substrate 20 and a semiconductor structure 30 is performed. The substrate 20 is an insulating substrate such as a sapphire substrate, for example. The semiconductor structure 30 is disposed on the substrate 20. The semiconductor structure 30 includes an n-side semiconductor layer 31, an active layer 32, and a p-side semiconductor layer 33. The n-side semiconductor layer 31 is disposed on the substrate 20, the active layer 32 is disposed on the n-side semiconductor layer 31, and the p-side semiconductor layer 33 is disposed on the active layer 32. A thickness T1 of the n-side semiconductor layer 31 is greater than a total thickness T2 of the p-side semiconductor layer 33 and the active layer 32. The thickness T1 of the n-side semiconductor layer 31 is, for example, 5.0 μm or more and 15.0 μm or less. The total thickness T2 of the p-side semiconductor layer 33 and the active layer 32 is, for example, 0.5 μm or more and 1.0 μm or less. For example, as the material of the semiconductor structure 30, a compound semiconductor such as a group III-V compound semiconductor or a group II-VI compound semiconductor is used, for example. For the semiconductor structure 30, a nitride semiconductor is used, for example.

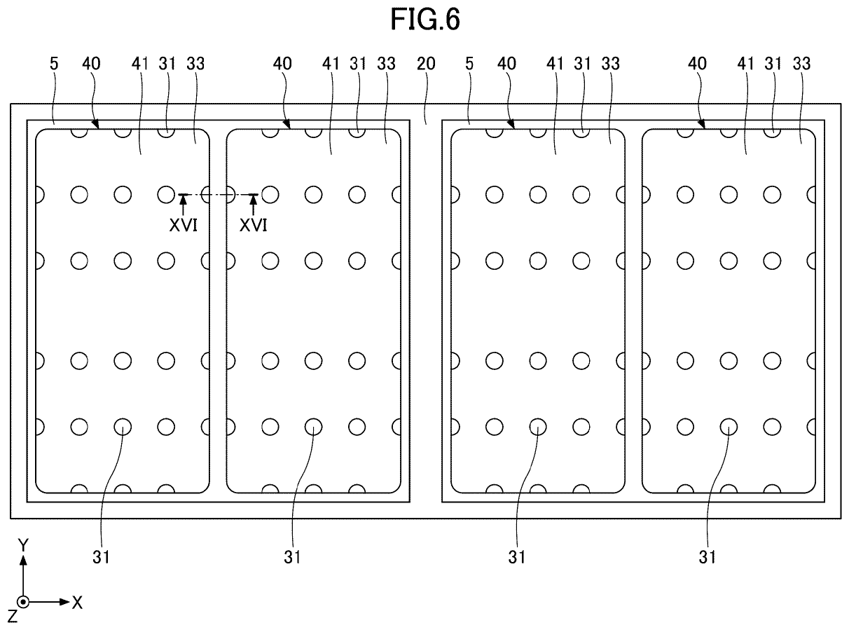

The wafer 10 has a plurality of chip regions 5 that are to serve as light-emitting elements 1. The shape of each of the chip regions 5 in a plan view is, for example, a rectangular shape having sides with lengths of 100 μm or more and 2,000 μm or less, and preferably 500 μm or more and 2,000 μm or less. The plurality of chip regions 5 are arranged at regular intervals in the X direction and the Y direction. For example, the distance between two adjacent chip regions 5 is, for example, 5 μm or more and 30 μm or less. In FIG. 1, two chip regions 5 arranged in the X direction are depicted. Each of the chip regions 5 has two first regions 41 where light-emitting element regions 40 illustrated in FIG. 6 are to be formed. The two first regions 41 are arranged in the X direction. The two first regions 41 are arranged in the X-direction. The shape of each of the first regions 41 in a plan view is a rectangular shape having short sides parallel to the X direction and long sides parallel to the Y direction. Each of the first regions 41 having a rectangular shape may have rounded corners. As illustrated in FIG. 8, each of the light-emitting elements 1 has two light-emitting element regions 40.

As illustrated in FIG. 9, a first region 41 has two first sides 41S parallel to each other and two second sides 41L longer than the first sides 41S and parallel to each other. The first sides 41S are parallel to the X direction, and the second sides 41L are parallel to the Y direction. The first region 41 has a third region 43 where the p-side semiconductor layer 33 and the active layer 32 are to be removed and the n-side semiconductor layer 31 is to be exposed, and a second region 42 where the p-side semiconductor layer 33 and the active layer 32 are to remain by not being removed.

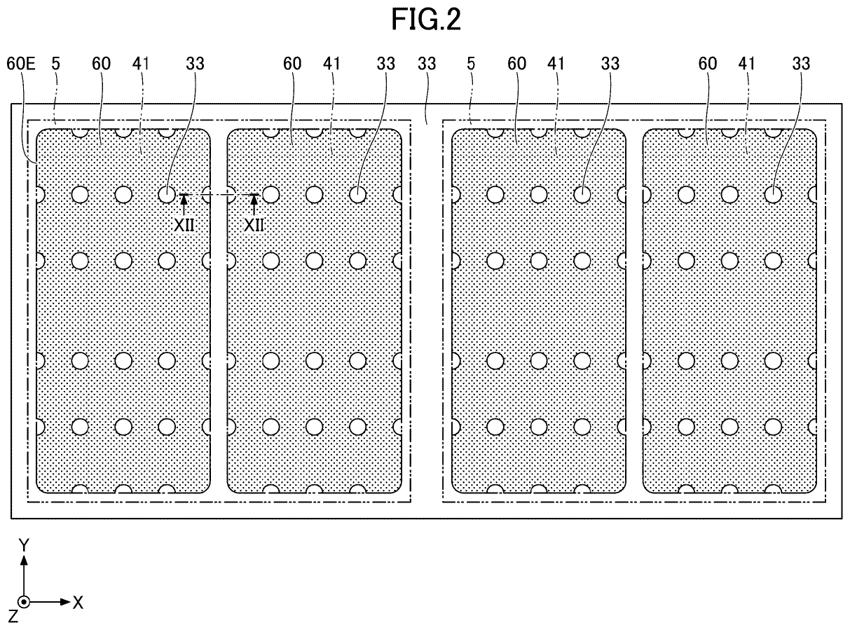

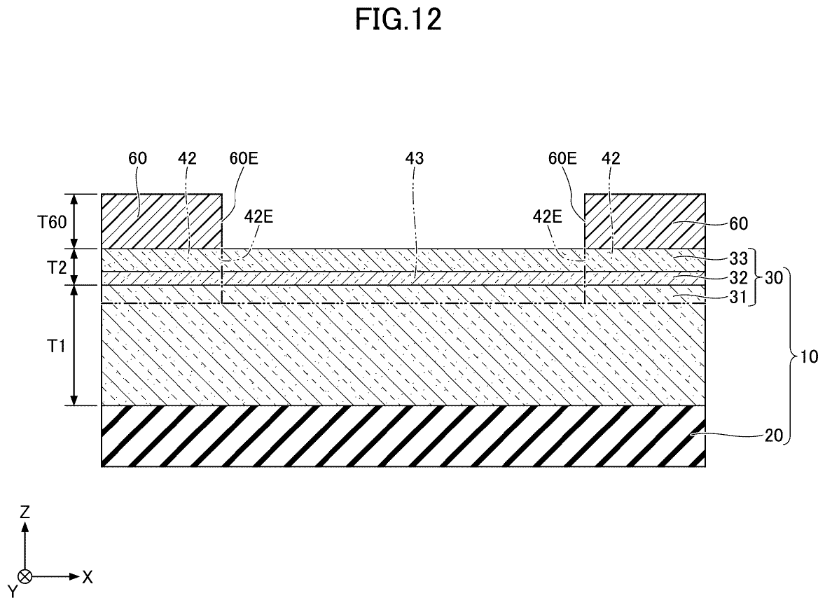

Next, as illustrated in FIG. 2 and FIG. 12, a step of forming a plurality of second masks 60 on the semiconductor structure 30 is performed. Each of the plurality of second masks 60 is formed in the second region 42 of the semiconductor structure 30, and the other portions (including the third region 43) of the semiconductor structure 30 are not covered by each of the second masks 60. At this time, in a plan view, an outer edge 60E of each of the plurality of second masks 60 coincides with an outer edge 42E of the second region 42. The second masks 60 are, for example, resist masks.

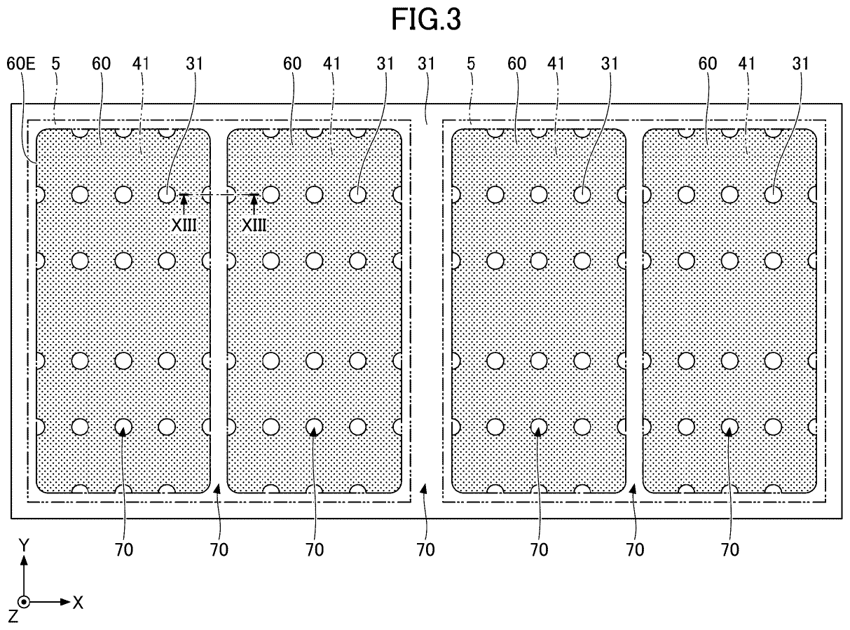

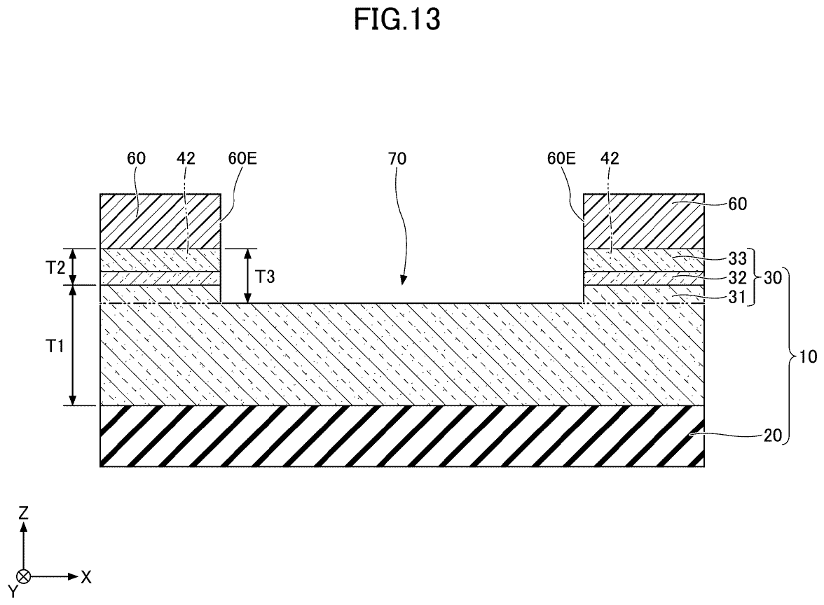

Next, as illustrated in FIG. 3 and FIG. 13, a step of exposing the n-side semiconductor layer 31 through the p-side semiconductor layer 33 and the active layer 32 by removing a portion of the semiconductor structure 30, which is not covered by each of the second masks 60, such that a thickness T3 of the removed portion is greater than the total thickness T2 of the p-side semiconductor layer 33 and the active layer 32 and is less than the thickness T1 of the n-side semiconductor layer 31 is performed. As a result, a recess 70 is formed in the removed portion of the semiconductor structure 30, which was not covered by each of the second masks 60. The thickness T3, that is, the depth of the recess 70 is, for example, 0.5 μm or more and 1.5 μm or less. The thickness of a portion of the n-side semiconductor layer 31 exposed through the p-side semiconductor layer 33 and the active layer 32 is, for example, 5.0 μm or more and 15.0 μm or less. The step of removing the semiconductor structure 30 is performed by, for example, reactive ion etching (RIE), and the temperature of the wafer 10 reaches approximately 100° C.

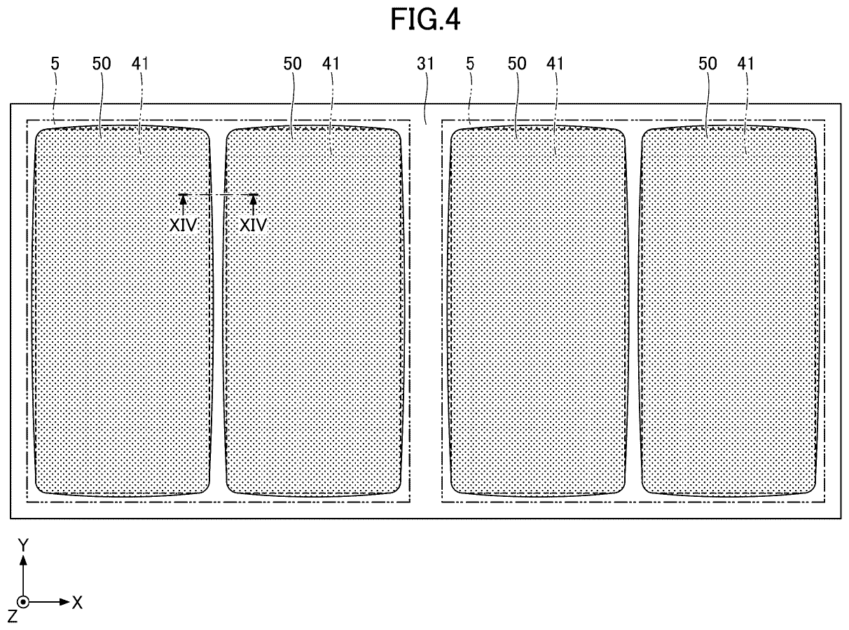

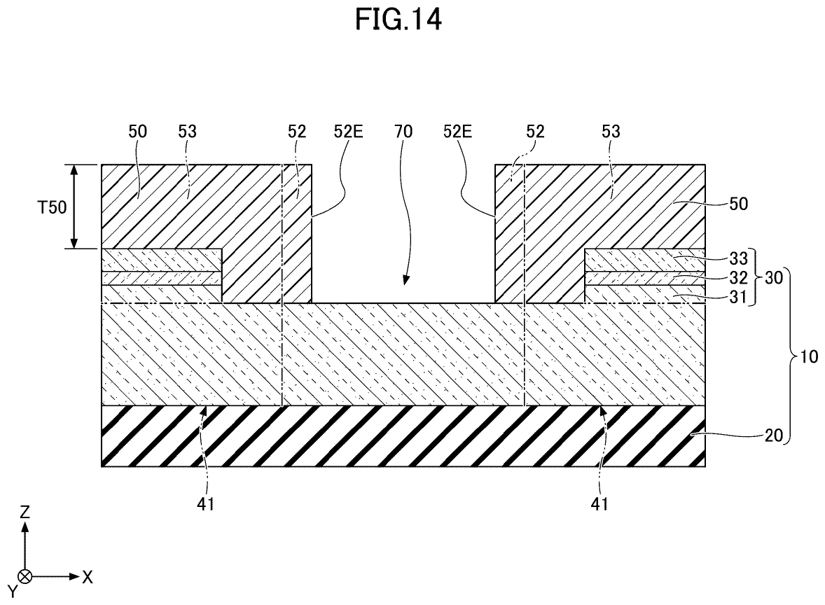

Next, as illustrated in FIG. 4 and FIG. 14, a step of removing the second masks 60 and forming a plurality of first masks 50 on the semiconductor structure 30 is performed. Each of the first masks 50 covers a respective first region 41 and has an area greater than the area of the respective first region 41 in a plan view.

As illustrated in FIG. 10, in a plan view, each of the first masks 50 includes a base portion 53, two first portions 51, and two second portions 52. In a plan view, the base portion 53 has a shape overlapping the first region 41 and having two third sides 53S and two fourth sides 53L. The third sides 53S are parallel to the first sides 41S of the first region 41, and the fourth sides 53L are longer than the third sides 53S and parallel to the second sides 41L of the first region 41. The third sides 53S are parallel to the X direction, and the fourth sides 53L are parallel to the Y direction. The first portions 51 are located outward of the second sides 41L of the first region 41 in a plan view, and the second portions 52 are located outward of the first sides 41S of the first region 41 in a plan view.

An outer edge 51E of each of the first portions 51 has a curved shape such that the outer edge 51E increases in distance from the base portion 53 as it approaches the middle between the two second portions 52 in the Y direction. In a plan view, a portion of the outer edge 51E of each of the first portions 51 has an arc shape so as to project outward from a corresponding fourth side 53L of the base portion 53 in a direction along a perpendicular bisector 55 of the corresponding fourth side 53L of the base portion 53. Further, an outer edge 52E of each of the second portions 52 has a curved shape such that the outer edge 52E increases in distance from the base portion 53 as it approaches the middle between the two first portions 51 in the Y direction. In a plan view, a portion of the outer edge 52E of each of the second portions 52 has an arc shape so as to project outward from a corresponding third side 53S of the base portion 53 in a direction along a perpendicular bisector 56 of the corresponding third side 53S of the base portion 53.

For example, in a plan view, a maximum distance L1 between the outer edge 51E of each of the first portions 51 and the corresponding fourth side 53L of the base portion 53 is longer than a maximum distance L2 between the outer edge 52E of each of the second portions 52 and the corresponding third side 53S of the base portion 53. The maximum distance L1 is preferably 1.2 times or more and 2.0 times or less, more preferably 1.3 times or more and 1.8 times or less, and even more preferably 1.4 times or more and 1.6 times or less the maximum distance L2. For example, the maximum distance L1 is 1.0 μm or more and 2.0 μm or less, and the maximum distance L2 is 0.5 μm or more and 1.5 μm or less.

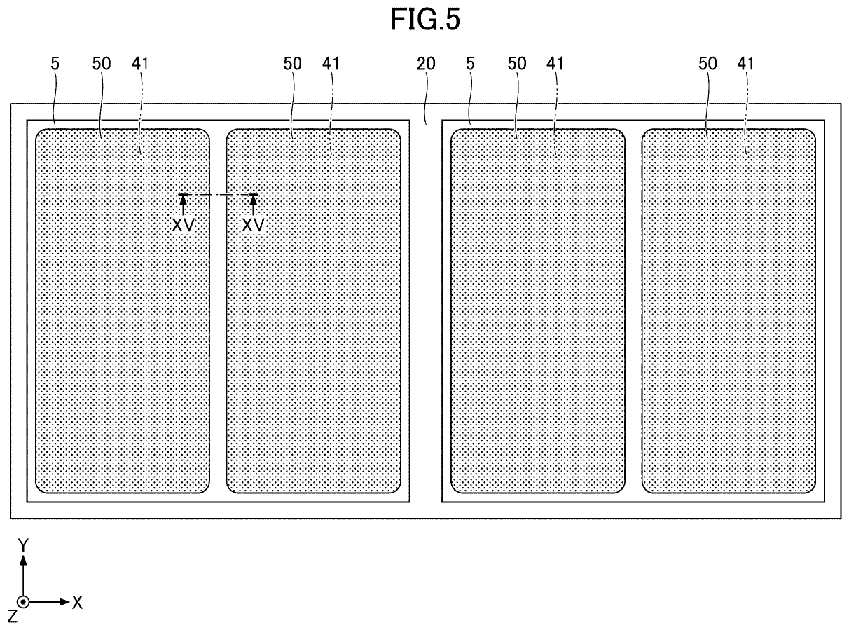

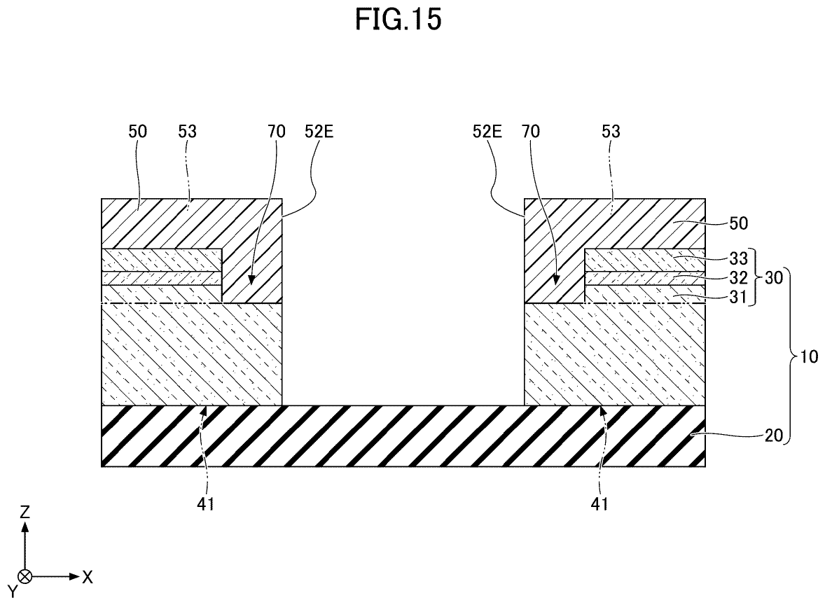

Next, as illustrated in FIG. 5 and FIG. 15, a step of exposing the substrate 20 through the semiconductor structure 30 by removing a portion of the semiconductor structure 30 that is not covered by each of the first masks 50 is performed. The step of removing the semiconductor structure 30 is performed by, for example, RIE as described above. During the RIE, the temperature of the wafer 10 reaches approximately 100° C., and the heat of the wafer 10 is transferred to the first masks 50. Therefore, while the RIE is performed, the temperature of the first masks 50 increases, and the first masks 50 gradually shrink. The amount of shrinkage increases as the volume of each of the first masks 50 increases. In a case where a relatively thick semiconductor layer is removed, the thickness of each of the first masks 50 needs to be increased in accordance with the thickness of the semiconductor layer. As described above, the thickness of a portion of the n-side semiconductor layer 31 that is not covered by each of the first masks 50 is, for example, 10.0 μm or more and 15.0 μm or less, and each of the first masks 50 has a thickness T50 in accordance with the thickness of the portion of the n-side semiconductor layer 31. For example, the thickness T50 is 10 μm or more and 20 μm or less. Therefore, the first masks 50 tend to shrink to a greater extent than a mask having a relatively small thickness. At this time, in each of the first masks 50 in a plan view, when the first portions 51 and the second portions 52 are compared, the first portions 51 shrink to a greater extent than the second portions 52, and each of the first portions 51 shrinks significantly in the vicinity of the perpendicular bisector 55. As a result, even when each of the first masks 50 has the first portions 51 and the second portions 52 that extend beyond the first region 41 in a plan view before the step of removing the semiconductor structure 30 using the first masks 50, the base portion 53, the first portions 51, and the second portions 52 of each of the first masks 50 shrink after the step of removing the semiconductor structure 30 using the first masks 50. Accordingly, each of the first masks 50 substantially entirely overlaps the first region 41. Further, the thickness of each of the first masks 50 is slightly reduced by the RIE.

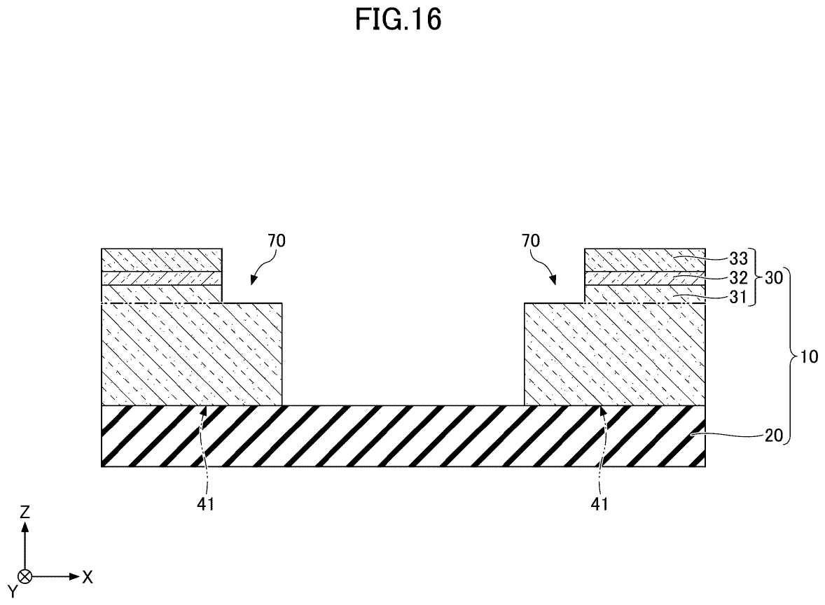

Next, as illustrated in FIG. 6 and FIG. 16, the first masks 50 are removed. In this manner, a plurality of light-emitting element regions 40 are formed by dividing the semiconductor structure 30. Each of the light-emitting element regions 40 is formed so as to substantially overlap the first region 41. In each of the light-emitting element regions 40, a portion of the n-side semiconductor layer 31 is exposed through the p-side semiconductor layer 33. Further, the substrate 20 is exposed to the surroundings of the light-emitting element regions 40. For example, the distance between two adjacent light-emitting element regions 40 in each of the chip regions 5 is 5 μm or more and 20 μm or less.

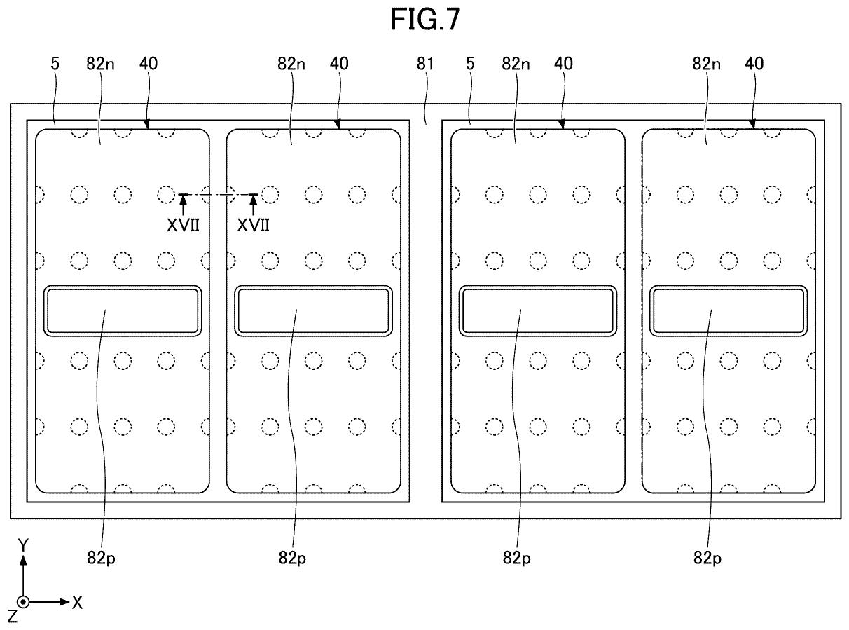

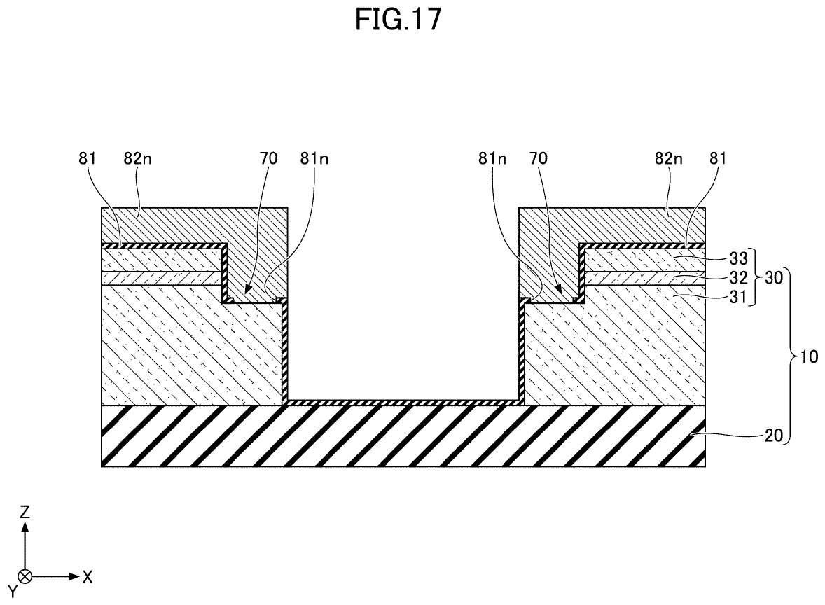

Next, as illustrated in FIG. 7 and FIG. 17, an insulating film 81 is formed so as to cover the light-emitting element regions 40 and the substrate 20. Next, an opening 81n that exposes the n-side semiconductor layer 31 and an opening (not illustrated) that exposes the p-side semiconductor layer 33 are formed in the insulating film 81. Next, an n-side electrode 82n electrically connected to the n-side semiconductor layer 31 through the opening 81n exposing the n-side semiconductor layer 31 and a p-side electrode 82p electrically connected to the p-side semiconductor layer 33 through the opening exposing the p-side semiconductor layer 33 are formed. For example, the insulating film 81 is an oxide film or a nitride film including at least one selected from the group consisting of Si, Ti, Zr, Nb, Ta, and Al. Examples of materials of the n-side electrode 82n and the p-side electrode 82p include metals such as Au, Pt, Pd, Rh, Ni, W, Mo, Cr, Ti, Al, and Cu, and alloys of these metals. Further, the n-side electrode 82n and the p-side electrode 82p may be formed of single-layer films or layered films.

Next, as illustrated in FIG. 8 and FIG. 18, the plurality of chip regions 5 are separated from each other by dividing the substrate 20. In this manner, a plurality of light-emitting elements 1 can be manufactured.

As described above, in the present embodiment, each of the first masks 50 includes the base portion 53, the first portions 51, and the second portions 52. The first masks 50 shrink while RIE is performed to remove a portion of the semiconductor structure 30 that is not covered by each of the first masks 50, and as a result of the shrinkage of the first masks 50, each of the first masks 50 substantially entirely overlaps the first region 41 when the RIE is completed. Therefore, a mismatch between the shape of the first region 41 in which a light-emitting element region 40 is to be formed and the shape of the light-emitting element region 40 obtained through the RIE can be reduced. The first region 41 corresponds to a designed light-emitting element region 40. Thus, according to the present embodiment, a mismatch between the shape of the designed light-emitting element region 40 and the shape of the obtained light-emitting element region 40 can be reduced.

The heat of the wafer 10 is transferred to the second masks 60 when RIE is performed to remove a portion of the semiconductor structure 30 that is not covered by each of the second masks 60, and as a result, the second masks 60 shrink. However, the second masks 60 do not substantially shrink, and the second region 42 is likely to remain covered by each of the second masks 60 during this step. This is because the thickness T3 of a portion to be removed in this step is, for example, 0.5 μm or more and 1.5 μm or less, and the second masks 60 can each have a thickness T60 in accordance with the thickness T3, and thus, the volume of each of the second masks 60 is small enough to ignore the amount of shrinkage. That is, the thickness T60 of each of the second masks 60 may be less than the thickness T50 of each of the first masks 50.

In addition, the first masks 50 are likely to shrink significantly at portions away from the four corners of the first masks 50 in a plan view. In the present embodiment, the maximum distance L1 is longer than the maximum distance L2. Thus, the first portions 51 tend to shrink to a greater extent than the second portions 52, and each of the first masks 50 is likely to entirely overlap the first region 41 as a result of the shrinkage of the first masks 50. By setting the maximum distance L1 to be 1.2 times or more and 2.0 times or less the maximum distance L2, each of the first masks 50 is particularly likely to entirely overlap the first region 41 as a result of the shrinkage of the first masks 50.

Further, in a plan view, a portion of the outer edge 51E of each of the first portions 51 has an arc shape so as to project from the corresponding fourth side 53L of the base portion 53 in the direction along the perpendicular bisector 55. Therefore, in a plan view, the outer edge 51E of each of the first portions 51 is likely to overlap the corresponding second side 41L of the first region 41 as a result of the shrinkage of the first masks 50.

According to the present disclosure, a method of manufacturing a light-emitting element that can reduce a mismatch between the shape of a designed light-emitting element region and the shape of an obtained light-emitting element region can be provided.

What is claimed is:

1. A method of manufacturing a light-emitting element, the method comprising:
preparing a wafer comprising a substrate, and a semiconductor structure disposed on the substrate; and
forming a plurality of light-emitting element regions by dividing the semiconductor structure, wherein the forming of the plurality of light-emitting element regions comprises:
forming a plurality of first masks on the semiconductor structure such that each of the plurality of first masks covers a respective first region where one of the plurality of light-emitting element regions is to be formed, and each of the plurality of first masks has an area greater than an area of the respective first region in a plan view, and
exposing the substrate through the semiconductor structure by removing a portion of the semiconductor structure that is not covered by the plurality of first masks.

2. The method of manufacturing the light-emitting element according to claim 1, wherein:
the first region has, in the plan view, a shape having two first sides and two second sides, the first sides being parallel to each other, and the second sides being longer than the first sides and parallel to each other,
each of the plurality of first masks comprises, in the plan view:
a base portion having a shape overlapping the first region and having two third sides and two fourth sides, the third sides being parallel to the first sides, and the fourth sides being longer than the third sides and parallel to the second sides,
a first portion located outward of a corresponding one of the second sides of the first region, and
a second portion located outward of a corresponding one of the first sides of the first region, and
a maximum distance between an outer edge of the first portion and a corresponding one of the fourth sides of the base portion is longer than a maximum distance between an outer edge of the second portion and a corresponding one of the third sides of the base portion in the plan view.

3. The method of manufacturing the light-emitting element according to claim 1, wherein:
the semiconductor structure comprises an n-side semiconductor layer disposed on the substrate, an active layer disposed on the n-side semiconductor layer, and a p-side semiconductor layer disposed on the active layer,
the forming of the plurality of light-emitting element regions includes, before the forming of the plurality of first masks:
forming a plurality of second masks on the semiconductor structure, and
exposing the n-side semiconductor layer through the p-side semiconductor layer and the active layer by removing a portion of the semiconductor structure that is not covered by the plurality of second masks such that a thickness of the removed portion is greater than a total thickness of the p-side semiconductor layer and the active layer and is less than a thickness of the n-side semiconductor layer.

4. The method of manufacturing the light-emitting element according to claim 2, wherein:
the semiconductor structure comprises an n-side semiconductor layer disposed on the substrate, an active layer disposed on the n-side semiconductor layer, and a p-side semiconductor layer disposed on the active layer,
the forming of the plurality of light-emitting element regions includes, before the forming of the plurality of first masks,
forming a plurality of second masks on the semiconductor structure, and
exposing the n-side semiconductor layer through the p-side semiconductor layer and the active layer by removing a portion of the semiconductor structure that is not covered by each of the plurality of second masks such that a thickness of the removed portion is greater than a total thickness of the p-side semiconductor layer and the active layer and is less than a thickness of the n-side semiconductor layer.

5. The method of manufacturing the light-emitting element according to claim 3, wherein:
in the forming of the plurality of second masks, in the plan view, an outer edge of each of the plurality of second masks coincides with an outer edge of a second region where the p-side semiconductor layer and the active layer are to remain, and
in the exposing of the n-side semiconductor layer through the p-side semiconductor layer and the active layer, the second region remains covered by each of the plurality of second masks.

6. The method of manufacturing the light-emitting element according to claim 4, wherein:
in the forming of the plurality of second masks, in the plan view, an outer edge of each of the plurality of second masks coincides with an outer edge of a second region where the p-side semiconductor layer and the active layer are to remain, and
in the exposing of the n-side semiconductor layer through the p-side semiconductor layer and the active layer, the second region remains covered by each of the plurality of second masks.

7. The method of manufacturing the light-emitting element according to claim 3, wherein a thickness of each of the plurality of first masks is greater than a thickness of each of the plurality of second masks.

8. The method of manufacturing the light-emitting element according to claim 5, wherein a thickness of each of the plurality of first masks is greater than a thickness of each of the plurality of second masks.

9. The method of manufacturing the light-emitting element according to claim 2, wherein in the plan view, the maximum distance between the outer edge of the first portion and the corresponding one of the fourth sides of the base portion is 1.2 times or more and 2.0 times or less the maximum distance between the outer edge of the second portion and the corresponding one of the third sides of the base portion.

10. The method of manufacturing the light-emitting element according to claim 2, wherein a portion of the outer edge of the first portion has an arc shape so as to project outward from the corresponding one of the fourth sides of the base portion in a direction along a perpendicular bisector of the corresponding one of the fourth sides of the base portion in the plan view.

11. The method of manufacturing the light-emitting element according to claim 1, wherein a thickness of each of the plurality of first masks is 10 μm or more and 20 μm or less.

12. The method of manufacturing the light-emitting element according to claim 2, wherein a thickness of each of the plurality of first masks is 10 μm or more and 20 μm or less.

13. The method of manufacturing the light-emitting element according to claim 3, wherein a thickness of each of the plurality of first masks is 10 μm or more and 20 μm or less.

14. The method of manufacturing the light-emitting element according to claim 1, wherein in the plan view, a distance between two adjacent ones of the light-emitting element regions is 5 μm or more and 30 μm or less.

15. The method of manufacturing the light-emitting element according to claim 2, wherein in the plan view, a distance between two adjacent ones of the light-emitting element regions is 5 μm or more and 30 μm or less.

16. The method of manufacturing the light-emitting element according to claim 3, wherein in the plan view, a distance between two adjacent ones of the light-emitting element regions is 5 μm or more and 30 μm or less.

17. The method of manufacturing the light-emitting element according to claim 9, wherein:
the maximum distance between the outer edge of the first portion and the corresponding one of the fourth sides of the base portion is 1.0 μm or more and 2.0 μm or less, and
the maximum distance between the outer edge of the second portion and the corresponding one of the third sides of the base portion is 0.5 μm or more and 1.5 μm or less.
